(19) United States
(12) Patent Application Publication
(10) Pub. No.: US 2016/0149033 A1
(43) Pub. Date: May 26, 2016

(54) INCREASING BREAKDOWN VOLTAGE OF LDMOS DEVICES FOR FOUNDRY PROCESSES

(71) Applicant: BROADCOM CORPORATION, Irvine, CA (US)

(72) Inventor: Akira ITO, Irvine, CA (US)

(21) Appl. No.: 14/562,654

(22) Filed: Dec. 5, 2014

Related U.S. Application Data
(60) Provisional application No. 62/084,460, filed on Nov. 25, 2014.

(51) Int. Cl. H01L 29/78; H01L 29/10; H01L 29/06; H01L 21/265; H01L 21/266; H01L 27/06; H01L 29/08; H01L 29/66

(52) U.S. Cl. CPC H01L 29/7823; H01L 29/0865; H01L 29/1095; H01L 29/0873; H01L 29/66681; H01L 21/26513; H01L 21/266; H01L 27/0617; H01L 29/0615

(57) ABSTRACT

A laterally defused MOS (LDMOS) device with improved breakdown voltage includes a substrate including a deep well, a drain region formed in the deep well and in contact with a first region of the deep well, and a source region formed in the deep well and in contact with a second region of the deep well. The doping concentrations of the first and second regions of the deep well are different from one another. A difference between the doping concentrations of the first and second regions of the deep well depends on an implant layout technique used to form the deep well.

### CROSS-REFERENCE TO RELATED APPLICATIONS

This application claims the benefit of priority under 35 §119 from U.S. Provisional Patent Application 62/084,460 filed Nov. 25, 2014, which is incorporated herein by reference in its entirety.

### TECHNICAL FIELD

The present description relates generally to integrated circuits, and more particularly, but not exclusively, to increasing breakdown voltage of laterally-diffused MOS (LDMOS) devices for foundry processes.

### BACKGROUND

As the operating voltage applied to a transistor (e.g., an MOS transistor) increases, the transistor may eventually breakdown allowing an uncontrollable increase in current to pass through devices of a circuit. Breakdown voltage is the voltage level where this uncontrollable increase in the current occurs. Examples of breakdown can include punch-through, avalanche breakdown, and gate oxide breakdown to provide some examples. Operating above the breakdown voltage for a significant duration reduces the lifetime of the transistor. In CMOS and BiCMOS processes, the device breakdown voltage is limited by P-well to N-well junction breakdown voltage (e.g., ˜12V) and can be improved by spacing the P-well and N-well apart.

### BRIEF DESCRIPTION OF THE DRAWINGS

Certain features of the subject technology are set forth in the appended claims. However, for purpose of explanation, several embodiments of the subject technology are set forth in the following figures.

FIGS. 1A-1C illustrate examples of an N-channel laterally diffused MOS (N-LDMOS) device before and after breakdown voltage improvement using an implant layout technique in accordance with one or more implementations.

FIG. 2 illustrates another example of an N-LDMOS device with breakdown voltage improvement using an implant layout technique in accordance with one or more implementations.

FIG. 3 illustrates examples of masks used for improvement of the breakdown voltage of an N-LDMOS in accordance with one or more implementations.

FIGS. 4A-4C illustrate examples of a P-channel LDMOS (P-LDMOS) device before and after breakdown voltage improvement using an implant layout technique in accordance with one or more implementations.

FIG. 5 illustrates an example of a method for providing an LDMOS device with improved breakdown voltage in accordance with one or more implementations.

FIG. 6 illustrates an example of a wireless communication device employing features of the subject technology in accordance with one or more implementations.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and can be practiced using one or more implementations. In one or more instances, well-known structures and components are shown in block diagram form in order to avoid obscuring the concepts of the subject technology.

In some aspects of the subject disclosure, methods and implementations for increasing breakdown voltage of LDMOS devices for foundries are disclosed. The subject technology enables increased breakdown voltage by lowering the effective doping of the DNW regions by layout techniques. It is understood that secondary foundries can provide a fairly matched process with respect to core and input/output (I/O) devices. These foundries, however, may use different DNW isolation profiles, which can result in variation in the breakdown voltage of LDMOS devices. The layout techniques of the disclosed solution, improves the breakdown voltage of LDMOS devices without the need to change foundry processes (e.g., DNW process), which is not easy to change.

LDMOS devices with breakdown voltage greater than ˜12V have been developed for a number of analog applications implemented in 65 nanometer (nm) technology node. For LDMOS devices, the breakdown voltage limitation is due to P-well to deep N-well (DNW) junction breakdown voltage. The subject technology enables creation of LDMOS devices with breakdown voltages of 15V in technology nodes such as 40 nm technology.

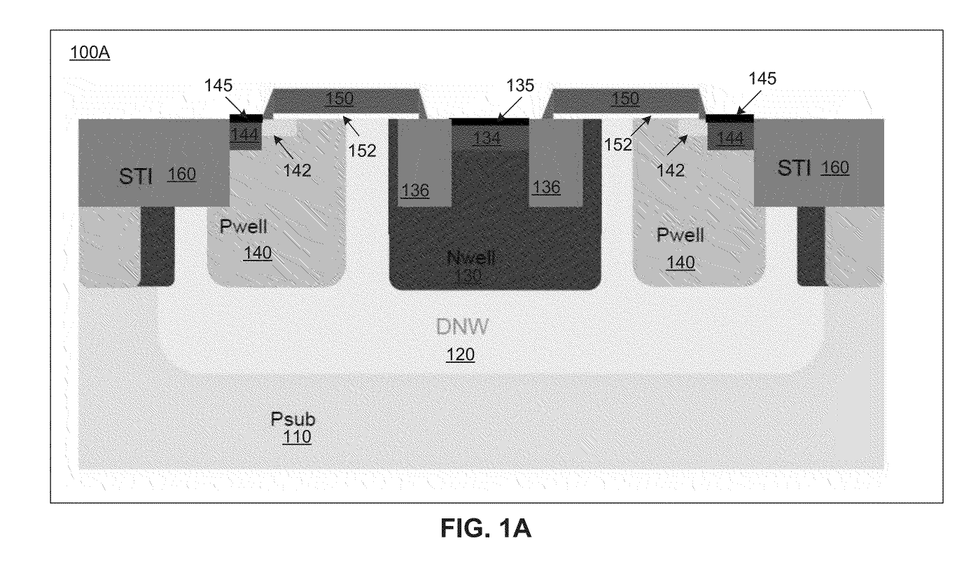

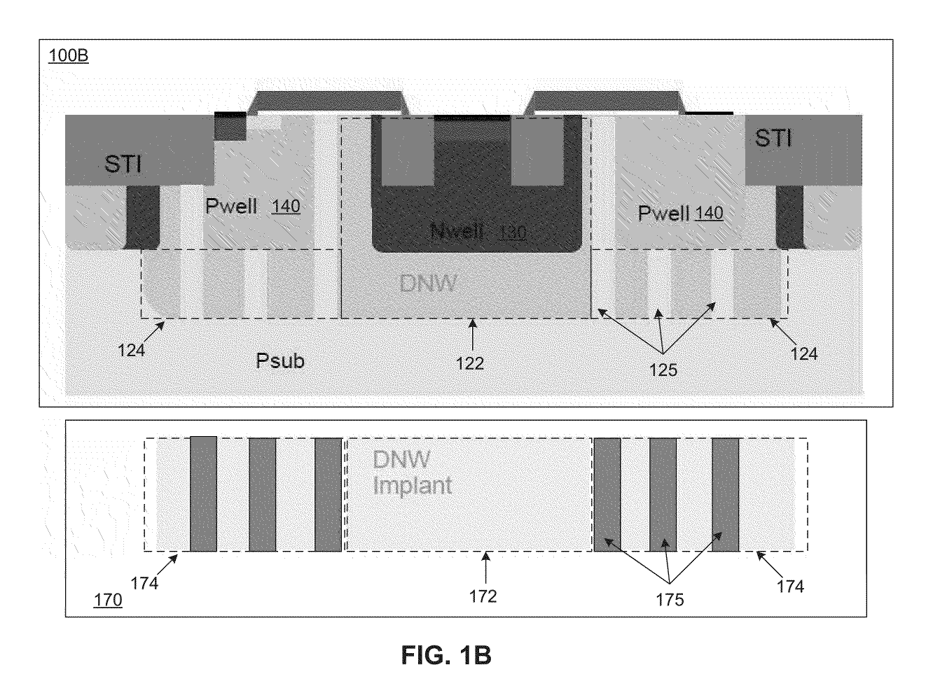

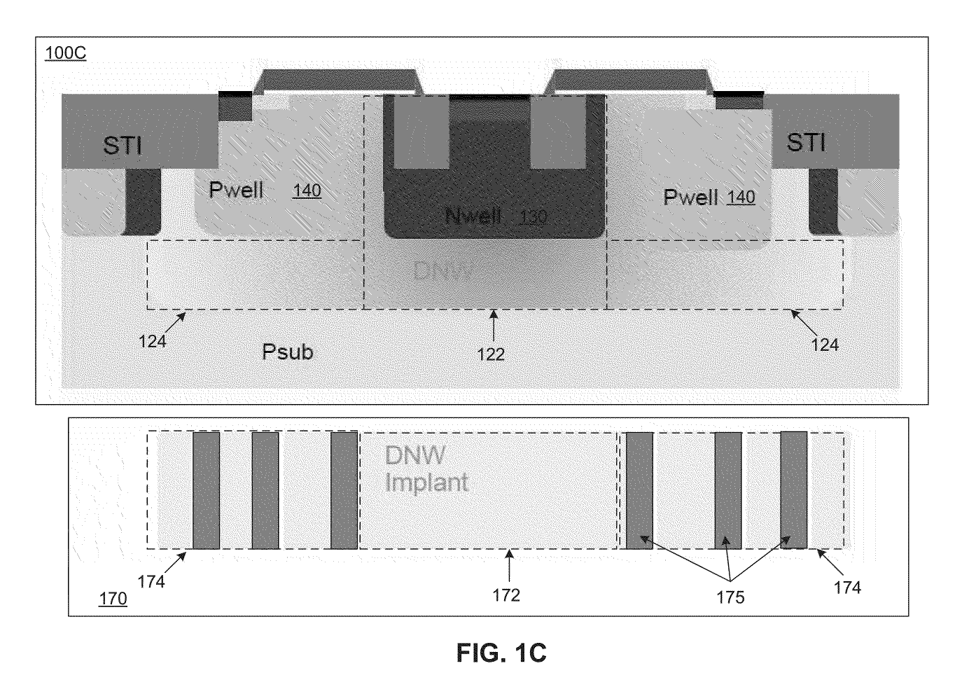

FIGS. 1A-1C illustrate examples 100A-100C of an N-channel laterally diffused MOS (N-LDMOS) device before and after breakdown voltage improvement using an implant layout technique in accordance with one or more implementations of the subject technology. The N-LDMOS device 100A includes a substrate 110 (e.g., a P-type substrate (Psub)), a deep well (e.g., a deep N-well (DNW)) 120, in which P-well regions 140 and N-well region 130 are created. The P-well regions 140 form the source regions and the N-well region 130 forms the drain region of the N-LDMOS device 100A. A gate, such as a poly-silicon gate 1150 is formed on an oxide or high-K material layer 152. The source and drain contacts (e.g., silicide) 145 and 135 are formed on a heavily doped p+ region 1144 and a heavily doped n+regions 134, respectively. Regions 142 formed in the P-well 140 are lightly doped n (n−) regions. Shallow trench isolation (STI) regions 136 enable creation of a longer length depletion region in the N-well 130, as the depletion region can form around the sides (e.g., walls and a bottom side) of the STI regions 136. The STI regions 160 are formed for isolation and protection for the LDMOS device 100A.

In one or more implementations, a breakdown voltage of the LDMOS device 100A can be improved (e.g., increased, for example, to 15 V for the 40 nm technology node) by using an implant layout technique, as described herein with respect to LDMOS device 100B of FIG. 1B. In one or more implementations, the implant layout technique includes using a mask 170 to create a first region 122 and a second region 124 of the DNW region (e.g., 120 of FIG. 1A), The mask 170 includes a first portion 172 and a second portion 174. The first portion 172 allows dopant (e.g., phosphine ions) to enter the first region 122 of the DNW 120. The second portion 1174 of the mask 170 includes stripes 175 that can block doping of corresponding regions 125 of the DNW 120 by the ion implant process. The dimensions of the strips 175 are determined by the smallest feature size of the applied technology node and the desired dopant concentration in the low doping concentration (e.g., ˜5×10¹⁵-˜1×10¹⁷ cm⁻³ of phosphorus) regions created by the implant layout technique. In some aspects, a difference between the doping concentrations of the regions 124 and 122 of the DNW depends on the details of the implant layout technique used to form the deep well, for example, the pattern of the mask 170, for example, a ratio of the areas of the striped to non-striped portions of the mask 170. In one or more implementations, this ratio is within 30-70% range, but is not limited to this range.

As a result of the employed implant layout technique, initially non-doped (e.g., via implant process) regions 125 are formed in the second region 124 of the DNW 120 that is in contact with the P-well 140 (e.g., a source region of the N-LDMOS 100B). The first region 122 that is in contact with the N-well 130 (e.g., a drain region of the N-LDMOS 100B) is fully doped with high doping concentration (e.g., 1×10¹⁷-˜5×10¹⁸cm⁻³ of phosphorus). The drain region (e.g., N-well 130) is formed in contact with the first region 122 of the deep well, and the source region (e.g., P-well 140) is formed in contact with the second region 124 of the deep well.

In one or more implementations, as shown in FIG. 1C, after ion implantation process using the mask 170, the diffusion of dopants from the high doping concentration regions (e.g., portions 125 of the second region 124 that is not blocked by stripes 175 and region 122) to the non-doped regions (e.g., portions of the second region 124 of the DNW 120 blocked by stripes 175) cause conversion of the second region 124 to low doping concentration regions. In other words, the low doping concentration regions 124 are the result of the implant layout technique of the subject technology, as opposed to being created by low dopant implant by the foundry. The low concentration regions 124 are in contact with the P-well regions 140, and provide a DNW isolation that results in a higher breakdown voltage of the junction between the DNW 120 and the P-well 140. The DNW isolation profile created by the implant layout technique of the subject technology when used by various foundries can result in a predictable breakdown voltage which is not foundry dependent. It is understood that existing DNW isolation profiles is different among various foundries, as the existing DNW implemented by the foundries is intended for device isolation. Thus, the breakdown voltage of the LDMOS devices fabricated by different foundries may be different. In one or more implementations, the mask 170 can be used for ion implantation of other portions of the LDMOS, as discussed herein.

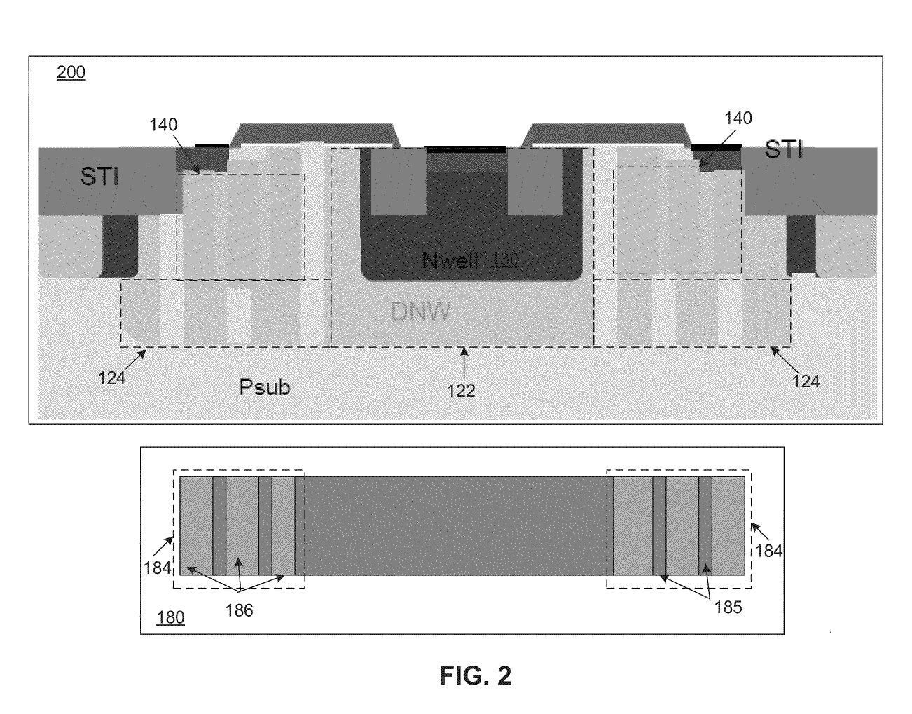

FIG. 2 illustrates another example of an N- LDMOS device 200 with breakdown voltage improvement using an implant layout technique in accordance with one or more implementations of the subject technology. The N- LDMOS device 200 is similar to the N-LDMOS device 100B of FIG. 1B, except that the N-well regions 140 which form the source regions of the N- LDMOS device 200 are created by the same implant layout technique discussed above. For example, a mask 180, with striped regions 184 having stripes 185 can be used to open windows corresponding to non-striped portions 186 for allowing p-type doping (e.g., through ion implantation) of portions of the P-well regions 140 under the non-striped portions 186 of the mask 180. The non-doped portions of the P-well regions 140 receives dopants from the doped portions of the P-well regions 140 due to the diffusion process, which brings the dopant concentrations of the non-doped and doped portion of the P-well regions 140 to an equilibrium. The reduced dopant concentration of the P-well due the diffusion of dopants can contribute to the improvement of the breakdown voltage across the junction of the P-well region 140 and the regions 124 of the DNW.

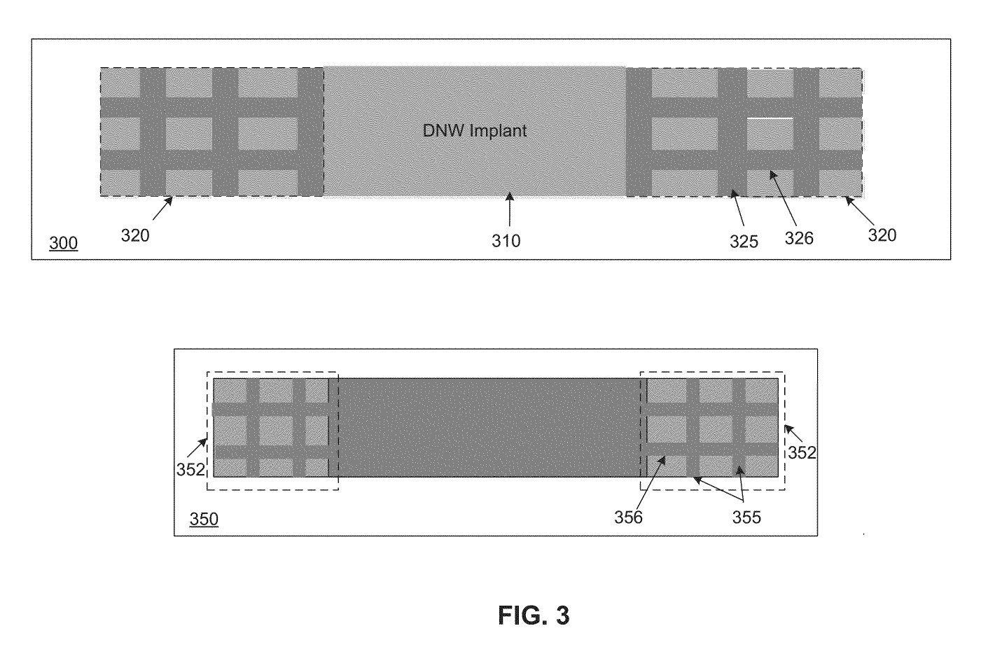

FIG. 3 illustrates examples of masks 300 and 350 used for improvement of the breakdown voltage of an N- LDMOS in accordance with one or more implementations of the subject technology. The mask 310 is similar to the mask 170 of FIG. 1B, except that the stripes are formed in two sets of stripes that are perpendicular to one another. For example, the striped regions 320 are not limited to vertical stripes 325 and include horizontal stripes 326 as well. The mask 350 is similar to the mask 180 of FIG. 2, except that the striped regions 352 includes horizontal stripes 356 in addition to the vertical stripes 355. The mask 350 can be used to create the P-well regions 140 of FIG. 2.

The two-dimensional stripe configurations of the masks 300 and 350 are not limited to the configurations shown in FIG. 3 and can have other configurations. In one or more implementations, this ratio of the striped to non-striped portions of the masks 300 and 350 is within 30-70% range, but is not limited to this range.

As explained above, the stripes of the masks 300 and 350 enable initial formation of high-doping concentration implant regions adjacent to non-doped regions in the DNW and the P-well that are blocked by the stripes. The initially formed non-doped regions are changed to low-doping concentration regions after diffusion of dopants from the high-doping concentration implant regions to non-doped regions. The higher breakdown voltage of the LDMOS device is due to a lower doping concentration in a deep-well region in contact with the P-well region, and the P-well regions having a gradient of dopant concentration, resulting from using the implant layout technique of the subject technology. In some implementations, the dimensions of the stripes are determined by the smallest feature size of the applied technology node and the desired dopant concentration in the low doping concentration regions created by the implant layout technique.

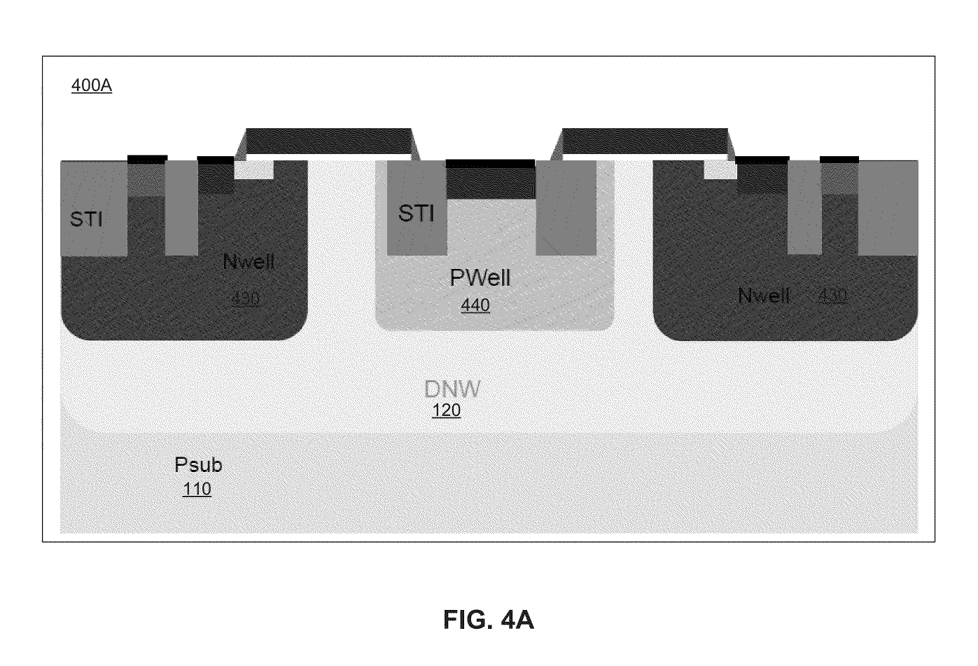

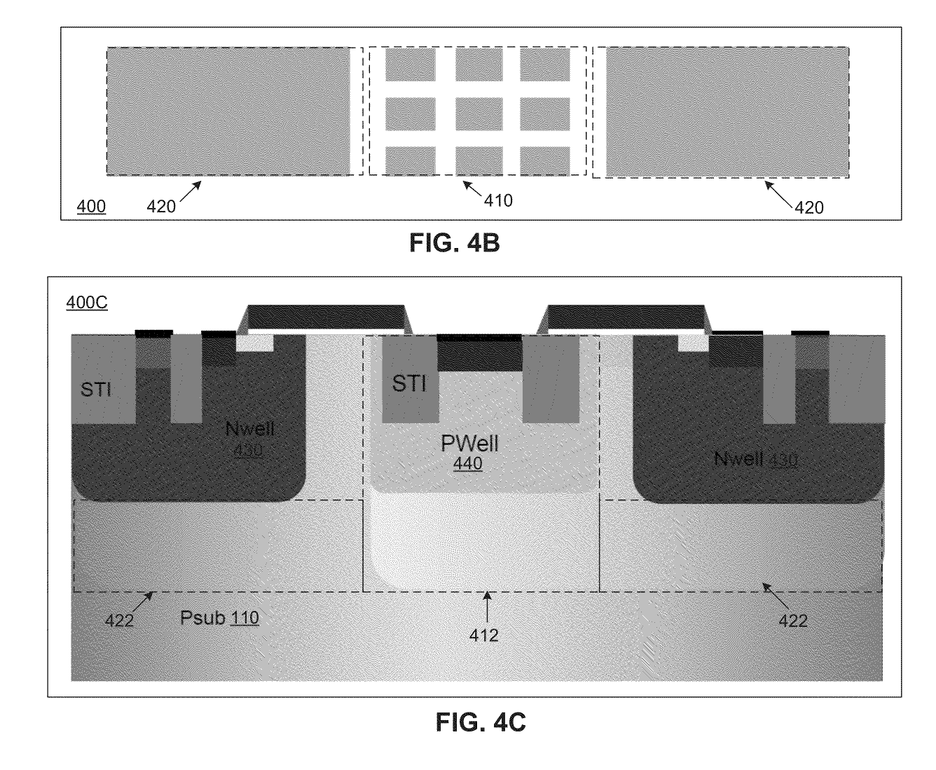

FIGS. 4A-4C illustrate examples of a P-channel LDMOS (P-LDMOS) device 400A before and after breakdown voltage improvement using an implant layout technique in accordance with one or more implementations of the subject technology. In the P-LDMOS device 400A, the P-well region 440 and the N-well regions 430 include the drain and source regions of the P-LDMOS device 400A, and are formed in the DNW region 120. The DNW region 120, as shown in FIG. 4A has uniform doping concentration. According to some implementations of the subject technology, as described with respect to the N-LDMOS device 100B of FIG. 1B, the disclosed implant layout technique can he employed to increase the breakdown voltage of the junction between the P-well region 440 and the DNW 120. For example, a mask 400 of FIG. 1B with striped portion 410 and non-striped portion 420 can be used when forming the DNW 120 in the substrate (e.g., Psub) 110. In some aspects, a mask with stripes only in vertical direction (e.g., similar to 175 of FIG. 1C) or horizontal direction only (e.g., similar to 326 of FIG. 3) can be used to form the DNW 120, which results in non-doped regions of the DNW in contact with the P-well region 440. As explained above, after the ion implantation process, the diffusion of dopants (e.g., implanted phosphine ions) from the doped portions to non-doped portions of the DNW forms a region with low level of doping concentration in the regions of the DNW in contact with the P-well region 440.

In the P-LDMOS device 400C of FIG. 4C, doping concentration in the regions 412 that are in contact with the P-well region 440 are lower than the regions 422 of the DNW, due to the implant layout technique used to form the DNW. As explained above, the lower dopant concentration in the region 412 of the DNW results in an increased breakdown voltage of the junction between the P-well 440 and the DNW.

In one or more implementations, the P-well region 440 can also be created using the implant layout technique as described with respect to P-well regions 140 of FIG. 2. This can further increase the P-well to DNW junction breakdown voltage.

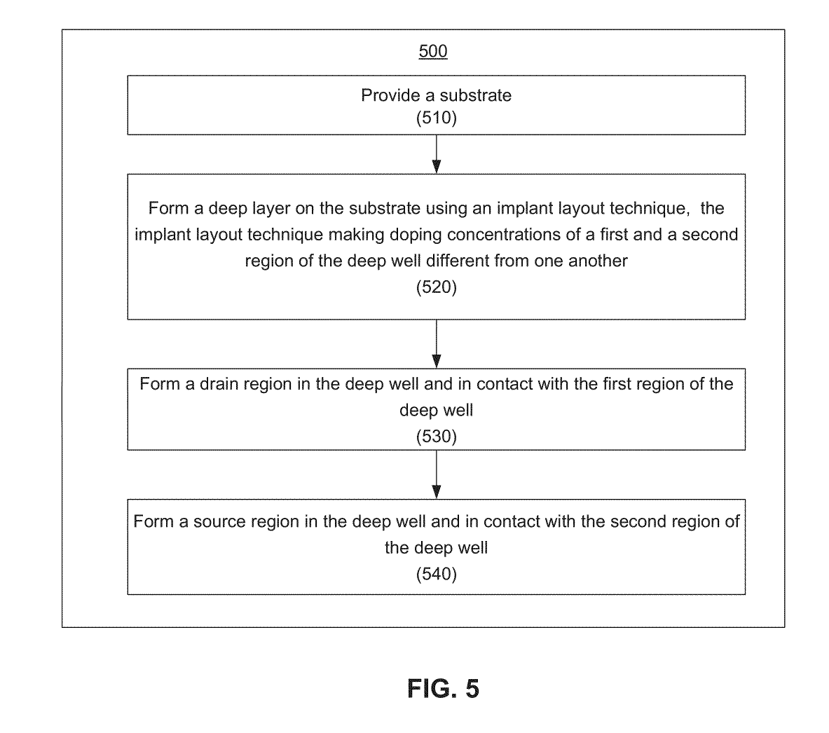

FIG. 5 illustrates an example of a method 500 for providing an LDMOS device (e.g., 100C of FIG. 1C or 400C of FIG. 4C) with improved breakdown voltage in accordance with one or more implementations of the subject technology. For explanatory purposes, the example method 500 is described herein with reference to, but is not limited to, the process disclosed with respect the devices 100C or 400C. Further, for explanatory purposes, the blocks of the example method 500 are described herein as occurring in serial, or linearly. However, multiple blocks of the example method 500 can occur in parallel. In addition, the blocks of the example method 500 need not be performed in the order shown and/or one or more of the blocks of the example method 500 need not be performed.

According to the method 500, a substrate (e.g., 110 of FIG. 1A) is provided (510). A deep well (e.g., 120 of FIG. 1A) is formed on the substrate using an implant layout technique (520). The implant layout technique makes doping concentrations of a first and a second region (e.g., 122 and 124 of FIG. 1B) of the deep well (e.g., 120 of FIG. 1A) different from one another. A drain region (e.g., 130 of FIG. 1B) is formed in the deep well and in contact with the first region (e.g., 122 of FIG. 1B) of the deep well (530). A source region (e.g., 140 of FIG. 1B) is formed in the deep well and in contact with the second region 124 of FIG. 1B) of the deep well (540).

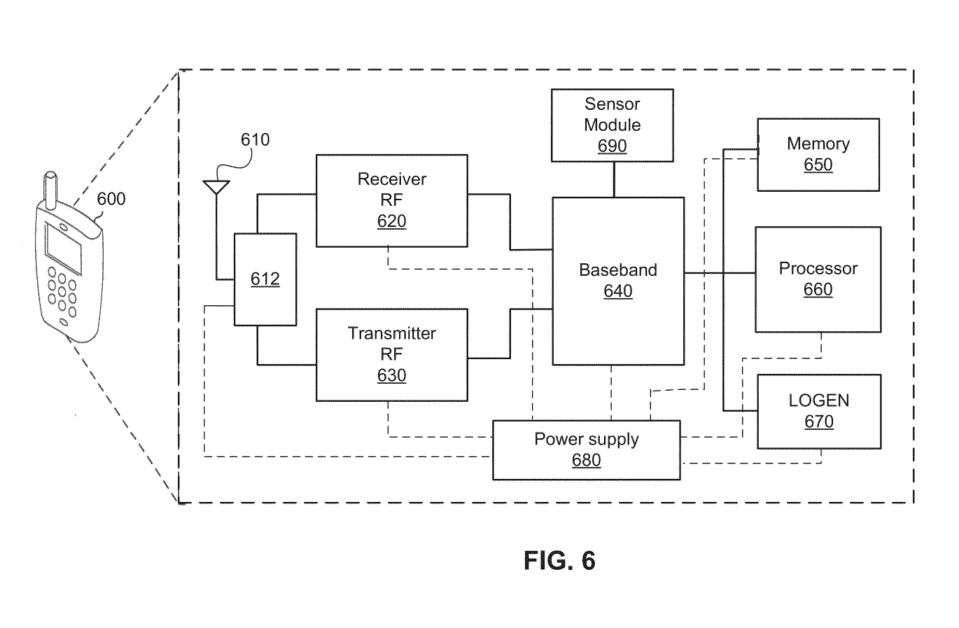

FIG. 6 illustrates an example of a wireless communication device employing features of the subject technology in accordance with one or more implementations of the subject technology. The wireless communication device 600 includes a radio-frequency (RF) antenna. 610, a receiver 620, a transmitter 630, a baseband processing module 640, a memory 650, a processor 460, a local oscillator generator (LOGEN) 670, a power supply 680 and a sensor module 690. In various embodiments of the subject technology, one or more of the blocks represented in FIG. 6 can be integrated on one or more semiconductor substrates. For example, the blocks 620-670 can be realized in a single chip or a single system on chip, or can be realized in a multi-chip chipset.

The RF antenna 610 can be suitable for transmitting and/or receiving RF signals (e.g., wireless signals) over a wide range of frequencies. Although a single RF antenna 610 is illustrated, the subject technology is not so limited.

The receiver 620 comprises suitable logic circuitry and/or code that can be operable to receive and process signals from the RF antenna 610. The receiver 620 may, for example, be operable to amplify and/or down-convert received wireless signals. In various embodiments of the subject technology, the receiver 620 is operable to cancel noise in received signals and can be linear over a wide range of frequencies. In this manner, the receiver 620 is suitable for receiving signals in accordance with a variety of wireless standards such as Wi-Fi, WiMAX, Bluetooth, and various cellular standards.

The transmitter 630 comprises suitable logic circuitry and/or code that can be operable to process and transmit signals from the RE antenna 610. The transmitter 630 may, for example, be operable to up-convert baseband signals to RF signals and amplify RF signals. In various embodiments of the subject technology, the transmitter 630 is operable to up-convert and to amplify baseband signals processed in accordance with a variety of wireless standards. Examples of such standards include Wi-Fi, WiMAX, Bluetooth, and various cellular standards. In various embodiments of the subject technology, the transmitter 630 is operable to provide signals for further amplification by one or more power amplifiers.

In some implementations, the transmitter 630 includes an RF power amplifier that can be a high-voltage power amplifier fabricated using the LDMOS device (e.g. as shown in FIGS. 1C or 4C) of the subject technology.

The duplexer 612 provides isolation in the transmit band to avoid saturation of the receiver 620 or damaging parts of the receiver 620, and to relax one or more design requirements of the receiver 620. Furthermore, the duplexer 612 can attenuate the noise in the receive band. The duplexer is operable in multiple frequency bands of various wireless standards.

The baseband processing module 640 comprises suitable logic, circuitry, interfaces, and/or code that can be operable to perform processing of baseband signals. The baseband processing module 640 may, for example, analyze received signals and generate control and/or feedback signals for configuring various components of the wireless communication device 600 such as the receiver 620. The baseband processing module 640 is operable to encode, decode, transcode, modulate, demodulate, encrypt, decrypt, scramble, descramble, and/or otherwise process data in accordance with one or more wireless standards.

The processor 660 comprises suitable logic, circuitry, and/or code that can enable processing data and/or controlling operations of the wireless communication device 600. In this regard, the processor 660 is enabled to provide control signals to various other portions of the wireless communication device 600. The processor 660 can also control transfers of data between various portions of the wireless communication device 600. Additionally, the processor 660 can enable implementation of an operating system or otherwise execute code to manage operations of the wireless communication device 600.

The memory 650 comprises suitable logic, circuitry, and/or code that can enable storage of various types of information such as received data, generated data, code, and/or configuration information. The memory 650 includes, for example, RAM, ROM, flash, and/or magnetic storage, In various embodiment of the subject technology, the memory 650 may include a RAM, DRAM, SRAM, T-RAM, Z-RAM, TTRAM, or any other storage media.

In some implementations, the memory 650 includes a memory chip (e.g., 400 of FIG. 4) including a bitcell process monitor (e.g., 420 of FIG. 4) that provides process variation information including process corners to an assist circuitry (e.g., 414 of FIG. 4) of the memory chip. The assist circuitry can use the process corners as well as temperature corners provided by a temperature monitor to improve performance of the memory 650, for example, by enabling low-voltage mode of operation of the memory 650, which results in lower power consumption and longer lifetime of the memory 650.

The local oscillator generator (LOGEN) 670 comprises suitable logic, circuitry, interfaces, and/or code that can be operable to generate one or more oscillating signals of one or more frequencies. The LOGEN 670 can be operable to generate digital and/or analog signals. In this manner, the LOGEN 670 can be operable to generate one or more clock signals and/or sinusoidal signals. Characteristics of the oscillating signals such as the frequency and duty cycle can be determined based on one or more control signals from, for example, the processor 660 and/or the baseband processing module 640.

In operation, the processor 660 can configure the various components of the wireless communication device 600 based on a wireless standard according to which it is desired to receive signals. Wireless signals can be received via the RF antenna 610 and amplified and down-converted by the receiver 620. The baseband processing module 640 can perform noise estimation and/or noise cancellation, decoding, and/or demodulation of the baseband signals. In this manner, information in the received signal can be recovered and utilized appropriately. For example, the information can be audio and/or video to be presented to a user of the wireless communication device, data to be stored to the memory 650, and/or information affecting and/or enabling operation of the wireless communication device 600. The baseband processing module 640 can modulate, encode and perform other processing on audio, video, and/or control signals to be transmitted by the transmitter 630 in accordance to various wireless standards.

In some implementations, the sensor module 690 includes one or more sensors, such as touch sensors that receive touch signals from a touch screen of the wireless communication device 600. In some aspects, the touch sensor module 690 includes sensor circuits including, for example, sensor drivers and other circuitry that use high breakdown voltage LDMOS of the subject technology.

Those of skill in the art would appreciate that the various illustrative blocks, modules, elements, components, and methods described herein can be implemented as electronic hardware, computer software, or combinations of both. To illustrate this interchangeability of hardware and software, various illustrative blocks, modules, elements, components, and methods have been described above generally in terms of their functionality. Whether such functionality is implemented as hardware or software depends upon the particular application and design constraints imposed on the overall system. Skilled artisans can implement the described functionality in varying ways for each particular application. Various components and blocks can be arranged differently (e.g., arranged in a different order, or partitioned in a different way) all without departing from the scope of the subject technology.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

A phrase such as “an aspect” does not imply that such aspect is essential to the subject technology or that such aspect applies to all configurations of the subject technology. A disclosure relating to an aspect can apply to all configurations, or one or more configurations. An aspect can provide one or more examples of the disclosure. A phrase such as an “aspect” refers to one or more aspects and vice versa. A phrase such as an “embodiment” does not imply that such embodiment is essential to the subject technology or that such embodiment applies to all configurations of the subject technology. A disclosure relating to an embodiment can apply to all embodiments, or one or more embodiments. An embodiment can provide one or more examples of the disclosure. A phrase such an “embodiment” can refer to one or more embodiments and vice versa. A phrase such as a “configuration” does not imply that such configuration is essential to the subject technology or that such configuration applies to all configurations of the subject technology. A disclosure relating to a configuration can apply to all configurations, or one or more configurations. A configuration can provide one or more examples of the disclosure. A phrase such as a “configuration” can refer to one or more configurations and vice versa.

The word “exemplary” is used herein to mean “serving as an example, instance, or illustration.” Any embodiment described herein as “exemplary” or as an “example” is not necessarily to be construed as preferred or advantageous over other embodiments. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein can be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e,g., her and its) and vice versa. Headings and subheadings, if any, are used for convenience only and do not limit the subject disclosure.

1. A laterally defused MOS (LDMOS) device with improved breakdown voltage, the device comprising:
a substrate including a deep well;
a drain region formed in the deep well and in contact with a first region of the deep well; and
a source region formed in the deep well and in contact with a second region of the deep well, wherein doping concentrations of the first and second regions of the deep well are different from one another, and wherein a difference between the doping concentrations of the first and second regions of the deep well depends on an implant layout technique used to form the deep well.

2. The device of claim 1, wherein the deep well comprises a deep N-well (DNW), and wherein the implant layout technique comprises using a mask including a plurality of stripes to implant the DNW.

3. The device of claim 2, wherein the LDMOS comprises an N-channel LDMOS (N-LDMOS), wherein the drain region comprises an N-well region and the source region comprises a P-well region, wherein the mask includes the plurality of stripes in portions of the mask corresponding to the second region of the deep well, and wherein the plurality of stripes are formed in two sets of stripes that are perpendicular to one another.

4. The device of claim 2, wherein the LDMOS comprises a P-channel LDMOS (P-LDMOS), wherein the drain region comprises a P-well region and the source region comprises an N-well region, wherein the mask includes the plurality of stripes in portions of the mask corresponding to the first region of the deep well, and wherein the plurality of stripes are formed in two sets of stripes that are perpendicular to one another.

5. The device of claim 4, wherein the plurality of stripes are configured to enable initial formation of high-doping concentration implant regions adjacent to non-doped regions in the deep well that are blocked by the plurality of stripes.

6. The device of claim 5, wherein the initially formed non-doped regions are changed to low-doping concentration regions after diffusion of dopants from the high-doping concentration implant regions to non-doped regions.

7. The device of claim 1, wherein the LDMOS comprises an N-channel LDMOS (N-LDMOS), wherein the drain region comprises an N-well region and the source region comprises a P-well region, wherein the implant layout technique comprises using masks including a plurality of stripes to implant at least one of the P-well region or the DNW.

8. The device of claim 7, wherein the mask used for creating the DNW includes the plurality of stripes in portions of the mask corresponding to the second region of the deep well, and wherein the plurality of stripes are formed in two sets of stripes that are perpendicular to one another.

9. The device of claim 1, wherein the device comprises a higher breakdown voltage LDMOS device, and wherein a higher breakdown voltage of the device is due to at least one of a lower doping concentration in a deep-well region in contact with a P-well region resulting from using the implant layout technique or variation in doping level of the P-well region resulting from using the implant layout technique.

10. A method for providing a laterally defused MOS (LDMOS) device with improved breakdown voltage, the method comprising:
providing a substrate;
forming a deep well on the substrate using an implant layout technique, wherein the implant layout technique makes doping concentrations of a first and a second region of the deep well different from one another;
forming a drain region in the deep well and in contact with the first region of the deep well; and
forming a source region in the deep well and in contact with the second region of the deep well.

11. The method of claim 10, wherein forming the deep well comprises forming a deep N-well (DNW), and wherein the method further comprises providing a first mask including a plurality of stripes, wherein using the implant layout technique comprises using the first mask to implant the DNW.

12. The method of claim 11, wherein the LDMOS comprises an N-channel LDMOS (N-LDMOS), wherein forming the drain region comprises forming an N-well region and forming the source region comprises forming a P-well region, wherein proving the first mask comprises providing the first mask including the plurality of stripes in portions of the first mask corresponding to the second region of the deep well, and wherein proving the first mask comprises providing the first mask including the plurality of stripes formed in two sets of stripes that are perpendicular to one another.

13. The method of claim 11, wherein the LDMOS comprises a P-channel LDMOS (P-LDMOS), wherein forming the drain region comprises forming a P-well region and forming the source region comprises an N-well region, wherein providing the first mask comprises providing the first mask including the plurality of stripes in portions of the mask corresponding to the first region of the deep well, and wherein providing the first mask comprises providing the first mask including the plurality of stripes formed in two sets of stripes that are perpendicular to one another.

14. The method of claim 11, wherein providing the first mask comprises configuring the plurality of stripes to enable initial formation of high-doping concentration implant regions adjacent to non-doped regions in the deep well that are blocked by the plurality of stripes.

15. The method of claim 14, wherein enabling initial formation of the high-doping concentration implant regions adjacent to the non-doped regions in the deep well allows formation of low-doping concentration regions after diffusion of dopants from the high-doping concentration implant regions to the non-doped regions.

16. The method of claim 10, wherein the LDMOS comprises an N-channel LDMOS (N-LDMOS), wherein the drain region comprises an N-well region and the source region comprises a P-well region, wherein the implant layout technique comprises providing masks including a plurality of stripes and using the masks to implant at least one of the P-well region or the DNW.

17. The method of claim 16, providing masks comprises providing a first mask for creating the DNW and a second mask for creating the P-well region, wherein providing the first mask comprises configuring the first mask to include the plurality of stripes in portions of the mask corresponding to the second region of the deep well, and wherein providing the masks comprises configuring the masks to include the plurality of stripes formed in two sets of stripes that are perpendicular to one another.

18. The method of claim 10, wherein the method comprises providing a higher breakdown voltage LDMOS device by using the implant layout technique to lower doping concentration in a deep-well region in contact with a P-well or to change a doping level of the P-well region.

19. A communication device, comprising:
one or more sensors; and
one or more sensor circuits, each sensor circuit including one or more high-voltage laterally defused MOS (LDMOS) device, the LDMOS device comprising:
a substrate including a deep well;
a drain region formed in the deep well and in contact with a first region of the deep well; and
a source region formed in the deep well and in contact with a second region of the deep well, wherein the deep well is formed by using an implant layout technique that allows formation of the first and second regions of the deep well with different doping concentrations.

20. The communication device of claim 19, wherein the one or more sensors comprise a touch screen sensor.

21. The communication device of claim 19, wherein using the implant layout technique comprises using a first mask to form the deep well.

22. The communication device of claim 19, wherein the P-well region is formed by using a second mask.

23. The communication device of claim 19, wherein the first and the second masks include a plurality of stripes, and wherein the plurality of stripes are formed in two sets of stripes that are perpendicular to one another.

24. A laterally-diffused MOS (LDMOS) device with improved breakdown voltage, the device comprising:
a substrate including a deep well comprising a first and a second region;
a drain region formed in the deep well and in contact with the first region; and
a source region formed in the deep well and in contact with the second region, wherein doping concentrations of the first and second regions are different from one another.

25. The device of claim 24, wherein a difference between the doping concentrations of the first and second regions depends on an implant layout technique used to form the deep well, and wherein the deep well comprises a deep N-well (DNW), and wherein the implant layout technique comprises using a mask including a plurality of stripes to implant the DNW.

26. The device of claim 25, wherein the LDMOS comprises an N-channel LDMOS (N-LDMOS), wherein the drain region comprises an N-well region and the source region comprises a P-well region, wherein the mask includes the plurality of stripes in portions of the mask corresponding to the second region, and wherein the plurality of stripes are formed in two sets of stripes that are perpendicular to one another.

27. The device of claim 25, wherein the LDMOS comprises a P-channel LDMOS (P-LDMOS), and wherein the drain region comprises a P-well region and the source region comprises an N-well region.

28. The device of claim 27, wherein the mask includes the plurality of stripes in portions of the mask corresponding to the first region, and wherein the plurality of stripes are formed in two sets of stripes that are perpendicular to one another.

29. The device of claim 28, wherein the plurality of stripes are configured to enable initial formation of high-doping concentration implant regions adjacent to non-doped regions in the deep well that are blocked by the plurality of stripes.
